(19) United States
(12) Patent Application Publication
(10) Pub. No.: US 2021/0125873 A1
(43) Pub. Date: Apr. 29, 2021

(54) SEMICONDUCTOR DEVICE AND FABRICATION METHOD THEREOF

(71) Applicant: INSTITUTE OF MICROELECTRONICS, CHINESE ACADEMY OF SCIENCES, Beijing (CN)

(72) Inventors: Yongliang LI, Beijing (CN); Hong YANG, Beijing (CN); Xiahong CHENG, Beijing (CN); Xiaolei WANG, Beijing (CN); Xueli MA, Beijing (CN); Wenwu WANG, Beijing (CN)

(21) Appl. No.: 16/924,057

(22) Filed: Jul. 8, 2020

(30) Foreign Application Priority Data
Oct. 28, 2019 (CN) 201911028106.1

(51) Int. Cl. H01L 21/8234; H01L 29/66; H01L 29/775; H01L 29/78; H01L 21/308; H01L 29/06; H01L 29/165; H01L 29/51; H01L 21/02

(52) U.S. Cl. CPC H01L 21/823431; H01L 29/6681; H01L 29/775; H01L 29/66545; H01L 29/7851; H01L 21/823437; H01L 29/0673; H01L 21/823481; H01L 29/165; H01L 29/517; H01L 21/02603; H01L 21/3086

(57) ABSTRACT

The disclosure provides a method for fabricating a semiconductor device, in which a core device of the semiconductor device employs a stacked nanowires or nanosheets structure, and an input/output device of the semiconductor device employs FinFET structure. The disclosure also provides a FinFET with an input/output device compatible with the stacked nanowires or nanosheets. The solution of the disclosure solves the problem that if the input/output device employs stacked nanowires or nanosheets device, it is difficult to fill a metal gate between two nanowires or nanosheets due to the thicker dielectric layer, and even if the metal gate is filled partially, the electrical performance of the input/output device is still poor.

### RELATED APPLICATION

The present application claims priority to Chinese Patent Application No. 201911028106.1, entitled “SEMICONDUCTOR DEVICE AND FABRICATION METHOD THEREOF” filed on 28 Oct. 2019, incorporated herein by reference.

### TECHNICAL FIELD

The disclosure relates to the field of semiconductors, and in particular, to a semiconductor device and a fabrication method thereof, a core device of the semiconductor device employs a stacked nanowires or nanosheets structure, and an input/output device of the semiconductor device employs FinFET structure.

### BACKGROUND

The core device refers to the device with the largest amount used inside the chip. In order to save power consumption, lower voltages are often used, generally 1.0V, 1.2V, 1.5V, and 1.8V. An input/output device (IO device) corresponds to the core device, that is, the device used when the chip interacts with the external interface. The working voltage of this type of device is generally high, such as, 1.8V, 2.5V, 3.3V, and 5V which depends on the compatibility with the external interface.

A lot of researches have been done on stacked nanowires or nanosheets as core devices while less research has been done on input/output devices compatible with them. In the prior art, it is difficult to directly integrate the fabricating process of the input/output device with the fabricating process of the core device. This is because that, in the case of the integration, the input/output device and the core device use the same stacked structure (e.g., SiGe/Si/SiGe/Si), use the same etching process for etching, form two same stacked fins and then form a dummy gate and a spacer, remove the sacrificial layer in the stacked fins to form the stacked nanowires or nanosheets in the two fins respectively, and then deposit a gate dielectric layer and a metal gate layer on the stacked nanowires or nanosheets in the core device region and the input/output device region, respectively. Since the two stacked fins of the core device and the input/output device are the same, distance between the stacked nanowires or nanosheets after release is very small, this can only meet the filling needs of the core device. However, the thickness of the gate dielectric layer of the input/output device located at the periphery of the chip is required to be thick. Therefore, the gate dielectric and the metal gate cannot be completely filled. Even if the metal gate is partially filled, the electrical performance of the input/output device will still be poor. Therefore, there is an urgent need to develop a FinFET comprising an input/output device compatible with stacked nanowires or nanosheets and a fabrication method thereof.

### BRIEF DESCRIPTION OF THE DRAWINGS

There is a known problem in the prior art, that is, the distance between the stacked nanowires or nanosheets after release is very small, and the high voltage of the input/output device requires a thicker gate dielectric layer thickness. Therefore, it is difficult to fill the metal gate between the two nanowires or nanosheets of the input/output device. Even if the metal gate is filled partially, the electrical performance of the input/output device will still be poor. To solve the problem, the disclosure provides a method for fabricating a semiconductor device, in which a core device of the semiconductor device employs a stacked nanowires or nanosheets structure, and an input/output device of the semiconductor device employs FinFET structure, comprising: providing a substrate including a first region and a second region, and forming sacrificial layers and first epitaxial layers alternately stacked on the substrate; removing the first epitaxial layers and the sacrificial layers in the second region, and forming a second epitaxial layer on the substrate in the second region; etching the substrate, the first epitaxial layers and the sacrificial layers in the first region, and the second epitaxial layer in the second region, and forming shallow trench isolation STI, a first fin protruding from the substrate in the first region, and a second fin protruding from the substrate in the second region, wherein the first fin and the second fin both extend in a first direction; forming a first dummy gate extending in a second direction across the first fin whilst forming a second dummy gate extending in the second direction across the second fin; forming a first spacer on a sidewall of the first dummy gate whilst forming a second spacer on a sidewall of the second dummy gate, wherein the second direction and the first direction are orthogonal in a plane where the substrate is located; removing the first dummy gate and forming the stacked nanowires or nanosheets in a portion of the first fin that is covered by the first dummy gate, and sequentially depositing a first gate dielectric layer and a first metal gate layer on a surface of the stacked nanowires or nanosheets to form a first gate; and removing the second dummy gate and sequentially depositing a second gate dielectric layer and a second metal gate layer, along the second direction, on a surface of a portion of the second fin that is covered by the second dummy gate to form a second gate.

Preferably, removing the first epitaxial layers and the sacrificial layers in the second region and forming a second epitaxial layer on the substrate in the second region comprises: depositing a hard mask on a top surface of the first epitaxial layer, forming a pattern on the hard mask using a photolithography process, and defining the second region; selectively removing the first epitaxial layer and the sacrificial layer in the second region by using a dry etching or a wet etching process; performing selective epitaxy of the second epitaxial layer on the substrate in the second region; planarizing or etching back the second epitaxial layer, so that the top of the second epitaxial layer is flush with the top of the hard mask in the first region; and removing the hard mask, so that a difference between heights of the first region and the second region is equal to a thickness of the hard mask.

Preferably, removing the first dummy gate, forming the stacked nanowires or nanosheets in a portion of the first fin that is covered by the first dummy gate comprises: removing the sacrificial layer in the first fin to form the stacked nanowires or nanosheets composed of the first epitaxial layer.

Preferably, after forming the first and second dummy gates and the first and second spacers, the method further comprises: epitaxially growing source and drain regions on the first fin on both sides of the first dummy gate along the first direction, and epitaxially growing source and drain regions on the second fin on both sides of the second dummy gate along the first direction.

Preferably, when the material of the first epitaxial layer is silicon; the material of the sacrificial layer is silicon germanium, or, when the material of the first epitaxial layer is silicon germanium; the material of the sacrificial layer is silicon.

The material of the second epitaxial layer comprises any one of silicon, silicon germanium, germanium, or III-V compound.

The material of the substrate comprises silicon or silicon-on-insulator.

Preferably, the first region is used to form a core device, and the second region is used to form an input/output device.

Preferably, the gate dielectric layer and the second gate dielectric layer comprise silicon dioxide and/or hafnium dioxide.

The disclosure also provides a semiconductor device, comprising: a substrate comprising a first region and a second region; a first fin extending along a first direction on a substrate in the first region; a first gate extending along a second direction across the first fin; wherein the first fin includes a plurality of first epitaxial layers, and in a portion of the first fin that is covered by the first gate, the plurality of first epitaxial layers are arranged at intervals and in a portion of the first fin that is not covered by the first gate, the plurality of first epitaxial layer and a plurality of sacrificial layers are alternately stacked; a second fin including a second epitaxial layer and extending in the first direction on the substrate in the second region; a second gate extending in a second direction on the second fin; wherein the first direction and the second direction are orthogonal in a plane where the substrate is located.

Preferably, the first region is adapted to form a core device; the second region is adapted to form an input/output device.

The material of the first epitaxial layer includes silicon or silicon germanium; the material of the second epitaxial layer includes any one of silicon, silicon germanium, germanium, or III-V compound; and the material of the substrate includes silicon or silicon on insulator.

The first gate and the second gate each include a gate dielectric layer and a metal gate layer, and the gate dielectric layer includes silicon dioxide and/or hafnium dioxide.

Preferably, the core device further comprises source and drain regions formed on the first fin on both sides of the first gate along the first direction, and the input/output device further comprises source and drain regions formed on the second fin on both sides of the second gate along the first direction.

The disclosure discloses a method for fabricating a semiconductor device, in which a core device of the semiconductor device employs a stacked nanowires or nanosheets structure, and an input/output device of the semiconductor device employs FinFET structure, including: after forming a stacked silicon germanium/silicon structure on a substrate, removing the stack on the substrate corresponding to the input/output device region, and then performing selective epitaxy of the second epitaxial layer on the substrate corresponding to the input/output device region; and then etching the substrate, the stack of the core device region, and the second epitaxial layer in the input/output device region to form a first fin protruding from the substrate in the core device region and a second fin protruding from the substrate in the input/output device region, which extends along the first direction, and forming a shallow channel isolation (STI) on the substrate to isolate the core device region and the input/output device region. In this way, the first fin is still a stacked structure, and the second fin becomes a single-layer structure composed of the second epitaxial layer.

The method further comprises simultaneously forming, for the first and second fins, the first dummy gate and the second dummy gate and the spacers on the sidewalls of the first dummy gate and the second dummy gate, wherein the first dummy gate crosses the first fin and covers a portion of the first fin and the second dummy gate crosses the second fin and covers a portion of the second fin; removing the first dummy gate, and removing the sacrificial layers in the stack in a portion of the first fin that is covered by the first dummy gate; forming the stacked nanowires or nanosheets composed of the first epitaxial layer arranged at intervals after removing the sacrificial layers; and sequentially depositing the gate dielectric layer and the metal gate layer on the surface of the stacked nanowires or nanosheets to form a first gate on the stacked nanowires or nanosheets. The first gate is a surrounding gate structure. The method further comprises removing the second dummy gate, and sequentially depositing a gate dielectric layer and a metal gate layer on the second fin to form a second gate. That is, a device having a FinFET structure is formed in an input/output device region.

Because the stacked nanowire structure is not used in the input/output device region, but a single-layer structure composed of the second epitaxial layer is used, the second fin formed is also a single-layer structure, and the second gate extends along the second direction at the second fin. That is, a gate dielectric layer and a metal gate layer are deposited on the top and sidewalls of the second fin along the second direction. Thus, the thickness is unlimited. There is no need to deposit the gate dielectric layer and the metal gate layer at the gap between the stacked nanowires or nanosheets after release like core devices. In this way, there is no need to concern the problem caused by a very small distance between the stacked nanowires or nanosheets after release which causes that it is difficult to fill the metal gate and even if the metal gate is filled partially, the electrical performance of the input/output device will still be poor.

### BRIEF DESCRIPTION OF THE DRAWINGS

In the following, the invention will be further explained with respect to the embodiments shown in the figures. It shows:

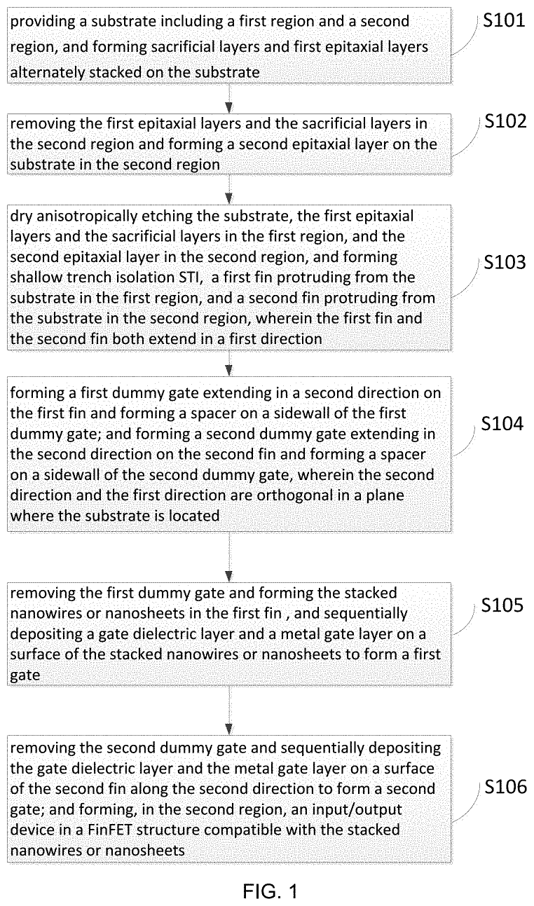

FIG. 1 is a flowchart of a method for fabricating a FinFET with an input/output device compatible with stacked nanowires or nanosheets according to an embodiment of the present disclosure;

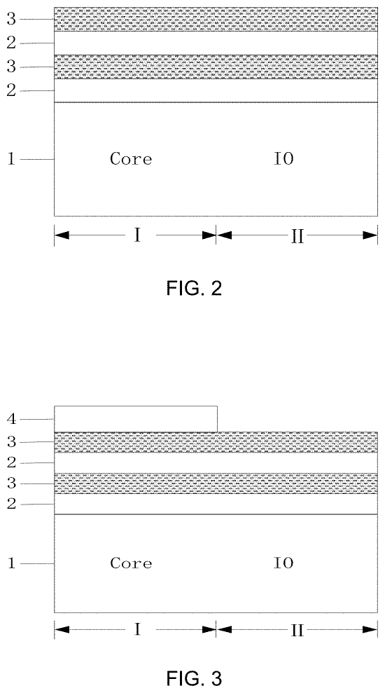

FIG. 2 to FIG. 8 and FIG. 10 to FIG. 12 are schematic structural diagrams along the second direction corresponding to each step in the method for fabricating a FinFET with an input/output device compatible with stacked nanowires or nanosheets in the embodiment of the present disclosure; and

FIG. 9 is a three-dimensional structural diagram after forming a first dummy gate, a second dummy gate, and a spacer in the embodiment of the present disclosure.

Where: 1. substrate, 2. sacrificial layer, 3. first epitaxial layer, 4. hard mask, 5. second epitaxial layer, 6. first dummy gate, 7. second dummy gate, 8. spacer 9. shallow trench isolation STI, 10. gate dielectric layer, 11. metal gate layer, I. First region, II. Second region.

### DETAILED DESCRIPTION

In order to make the foregoing objects, features, and advantages of this application more comprehensible, specific implementations of the present application will be described in detail below with reference to the accompanying drawings.

In the following description, many specific details are set forth in order to fully understand this application, but this application can also be implemented in other ways than described here, and those skilled in the art can do similar modification without violating the connotation of this application. Hence, this application is not limited by the specific embodiments disclosed below.

Secondly, the present application is described in detail with reference to the schematic diagrams. In the detailed description of the embodiments of the present application, for convenience of explanation, the cross-sectional view showing the structure of the device will not be partially enlarged according to the general scale, and the schematic diagrams are merely examples, which should not limit the scope of protection of this application herein. In addition, the actual production should include three-dimensional space dimensions of length, width and depth.

As described in the background art, in the prior art, the same stacked structure is used for the core device and the input/output device, and the same fin is formed by etching. A dummy gate is formed both in the core device region and the input/output device region, and then the two dummy gates are removed. The sacrificial layers in the stacks of the two fins are removed, and the same stacked nanowires or nanosheets are formed both in the core device region and the input/output device region, and then the gate dielectric layer and metal gate layer are respectively deposited on the stacked nanowires or nanosheets in the core device region and the input/output device region. As the distance between the stacked nanowires or nanosheets after release is very small, this can only meet the core device filling requirements. The thickness of the gate dielectric layer of the input/output devices located on the periphery of the chip is required to be thick, so it is impossible to fill the gate dielectric layer and the metal gate layer completely. For example, the thickness of the atomic layer deposited silicon dioxide film (ALD SiO2) corresponding to the high voltage of the input/output device is 3 nm to 5 nm, plus the thickness of the high-k dielectric of hafnium dioxide of 2 nm. If the nanowires or nanosheets are used in the input/output region, the thickness of the gate dielectric layer, which is a stack of a high-k dielectric and a silicon dioxide and deposited between the two nanowires or nanosheets, is (3+2)*2=10 nm to (5+2)*2=14 nm. At this time, it is difficult to fill the metal gate between the two nanowires or nanosheets in the input/output device region.

Based on this, the present disclosure provides a method for fabricating a FinFET with an input/output device compatible with stacked nanowires or nanosheets, in which the stacked nanowires or nanosheets are integrated with the input/output device compatible with stacked nanowires or nanosheets. The present disclosure does not form the same stacked nanowires or nanosheets for the input/output device region as for the core device region, but changes the same stacked structure as the core device region to a single layer structure composed of a second epitaxial layer, and after removing the second dummy gate on the second fin, forms a gate dielectric layer and a metal gate layer on the top and two sidewalls of a portion of the second fin that is covered by the second dummy gate along the second direction, i.e., the second gate. The second gate is a triple-gate structure. In the present disclosure, the method for forming the second gate in the input/output device region and the method for forming the first gate in the core device region are different. The coverage regions of the two gates are also different. Each nanowire or nanosheet in the core device region is a four-side surrounding gate structure. The triple-gate structure is formed on the second fin in the input/output device region; therefore, there is no need to form a gate dielectric layer and a metal gate layer at the gap of the stacked nanowires or nanosheets after release. It is no need to consider the problem caused by a small distance between the stacked nanowires or nanosheets after release, which makes it difficult to fill the metal gate.

The disclosure provides a method for fabricating a semiconductor device, in which a core device of the semiconductor device employs a stacked nanowires or nanosheets structure, and an input/output device of the semiconductor device employs FinFET structure, comprising: providing a substrate including a first region and a second region, and forming sacrificial layers and first epitaxial layers alternately stacked on the substrate; removing the first epitaxial layers and the sacrificial layers in the second region, and forming a second epitaxial layer on the substrate in the second region; etching the substrate, the first epitaxial layers and the sacrificial layers in the first region, and the second epitaxial layer in the second region, and forming shallow trench isolation STI, a first fin protruding from the substrate in the first region, and a second fin protruding from the substrate in the second region, wherein the first fin and the second fin both extend in a first direction; forming a first dummy gate extending in a second direction across the first fin whilst forming a second dummy gate extending in the second direction across the second fin; forming a first spacer on a sidewall of the first dummy gate whilst forming a second spacer on a sidewall of the second dummy gate, wherein the second direction and the first direction are orthogonal in a plane where the substrate is located; removing the first dummy gate and forming the stacked nanowires or nanosheets in a portion of the first fin that is covered by the first dummy gate, and sequentially depositing a first gate dielectric layer and a first metal gate layer on a surface of the stacked nanowires or nanosheets to form a first gate; removing the second dummy gate and sequentially depositing a second gate dielectric layer and a second metal gate layer, along the second direction, on a surface of a portion of the second fin that is covered by the second dummy gate to form a second gate. The disclosure also provides a FinFET with an input/output device compatible with the stacked nanowires or nanosheets. The solution of the disclosure solves the problem that if the input/output device employs stacked nanowires or nanosheets device, it is difficult to fill a metal gate between two nanowires or nanosheets due to the thicker dielectric layer, and even if the metal gate is filled partially, the electrical performance of the input/output device is still poor.

In order to better understand the technical solutions and technical effects of the present disclosure, specific embodiments will be described in detail below with reference to the flowcharts of FIG. 1 and FIGS. 2-12.

As shown in FIG. 1, a method for fabricating a FinFET with an input/output device compatible with stacked nanowires or nanosheets according to an embodiment of the present disclosure includes the following steps:

S101: Providing a substrate 1. The substrate 1 includes a first region I and a second region II. Sacrificial layers 2 and first epitaxial layers 3 are alternately stacked on the substrate 1, as shown in FIG. 2.

It should be noted that the substrate 1 includes a first region I and a second region II. The first region I is adapted to form a core device, so it is also called a core device region I. The second region II is adapted to form an input/output (IO) device, so it is also called an input/output device region II.

The substrate 1 may be a silicon substrate, a germanium substrate, a silicon germanium (SiGe) substrate, a silicon-on-insulator (SOI) substrate, a germanium-on-insulator (GOI) substrate, a III-V compound substrate or a II-IV compound substrate.

In this embodiment, the substrate 1 is preferably a silicon substrate, and the sacrificial layers 2 and the first epitaxial layers 3 are alternately and epitaxially stacked on the substrate 1.

Specifically, a sacrificial layer 2 is epitaxially grown on the substrate 1, and then a first epitaxial layer 3 is epitaxially grown on the sacrificial layer 2. The sacrificial layer 2 and the first epitaxial layer 3 cover the entire substrate 1. Growth process can be reduced pressure epitaxy or molecular beam epitaxy. Among others, the material of the first epitaxial layer 3 includes silicon, germanium, silicon germanium, silicon carbide, gallium arsenide, or indium gallium. The material of the sacrificial layer 2 is easy to be subsequently removed which is different from the material of the first epitaxial layer 3. Preferably, the material of the first epitaxial layer 3 is silicon with a thickness of 5 to 50 nm, and the material of the sacrificial layer 2 is silicon germanium (SiGe) with a thickness of 5 to 50 nm. In order to facilitate the subsequent removal of the sacrificial layer 2, in the sacrificial layer 2, the mass percentage of germanium (Ge) is 5% to 100%, preferably 5% to 30%.

On the substrate 1, a stack of two, three, or more epitaxial layers composed of a sacrificial layer 2 and a first epitaxial layer 3 is formed on a substrate 1. The specific number of the stacked layers needs to be set according to the actual situation. According to a specific embodiment as shown in the structure of FIG. 2, two stack layers each composed of a first sacrificial layer 2 and a first epitaxial layer 3 is epitaxially grown on a substrate 1 to form two stacked nanowires.

S102: Removing the first epitaxial layer 3 and the sacrificial layer 2 in the input/output device region II, and forming a second epitaxial layer 5 on the substrate corresponding to the input/output device region II.

It should be noted that the following steps are used:

First, a hard mask is deposited on the surface of the top first epitaxial layer 3, and a pattern is formed on the hard mask using a photolithography process to define an input/output device region II, and then selectively removing the hard mask on the input/output device region II by a dry etching or wet etching process, and removing the photoresist covering the core device region Ito form a hard mask 4 only on the core device region I (see FIG. 3), thereby defining the input/output device region II, wherein the hard mask 4 includes a stack of silicon dioxide or silicon dioxide/silicon nitride or silicon dioxide/silicon nitride/silicon dioxide.

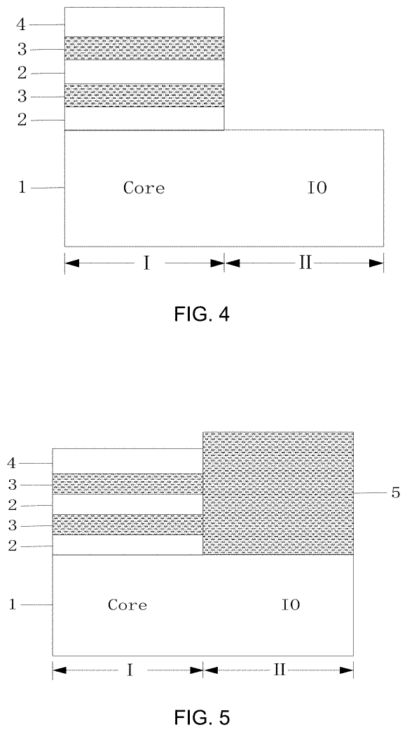

The etching is performed according to the pattern of the hard mask 4, and dry etching or wet etching is used to remove the sacrificial layer 2 and the first epitaxial layer 3 in the input/output device region II to the substrate 1 (see FIG. 4), preferably the wet etching.

The second epitaxial layer 5 is selectively epitaxially formed on the substrate corresponding to the input/output device region II. The material of the second epitaxial layer 5 includes silicon, germanium, silicon germanium, or a III-V compound, and preferably, silicon is epitaxially grown on the substrate corresponding to the input/output device region II, and the thickness of the epitaxial silicon is greater than the thickness of the stack of the sacrificial layer 2 and the first epitaxial layer 3 in the core device region I (see FIG. 5).

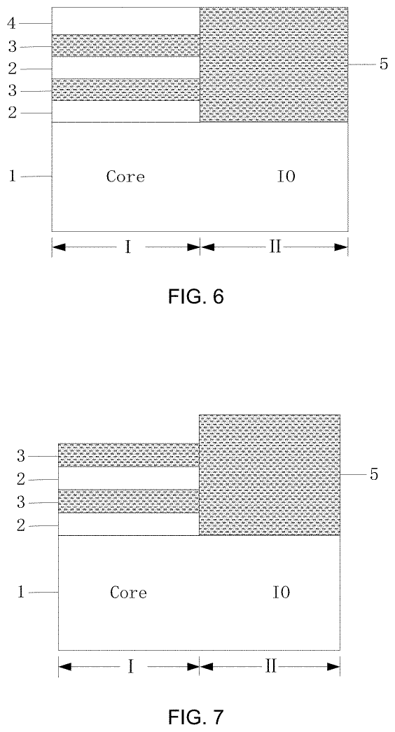

The epitaxial second epitaxial layer 5 is subjected to CMP planarization processing or etch-back so that the top of the second epitaxial layer 5 is flush with the top of the hard mask 4 in the core device region I (see FIG. 6). That is, the second epitaxial layer 5 is planarized by a combination of chemical reaction and mechanical polishing, or the second epitaxial layer 5 in the input/output device region II is etched back by dry etching. The etching gas for dry etching includes C4F8, C4F6, HBr, Cl2, SF6, or a mixed gas thereof. Preferably, the second epitaxial layer 5 is removed by a planarization process, so that the top of the second epitaxial layer 5 is flush with the top of the hard mask 4 in the core device region I, so as to reduce the height difference between the stack formed by the sacrificial layer 2, the first epitaxial layer 3 and the hard mask 4 in the core device region I and the second epitaxial layer 5 in the input/output device region II.

The wet etching or dry etching process is used to remove the hard mask 4 deposited in the core device region I, so that the height difference between the stack formed by the remaining sacrificial layer 2 and the first epitaxial layer 3 in the core device region I and the second epitaxial layer 5 in the input/output device region II is equal to the thickness of the hard mask 4 (see FIG. 7).

S103: dry anisotropic etching the substrate 1, the first epitaxial layer 3 and the sacrificial layer 2 in the core device region I, and the second epitaxial layer 5 in the input/output device region II, and then form shallow channel isolation STI 9, so that the first fin protrudes from the substrate corresponding to the core device region I, and the second fin protrudes from the substrate corresponding to the input/output device region II. The first fin and the second fin both extend in the first direction.

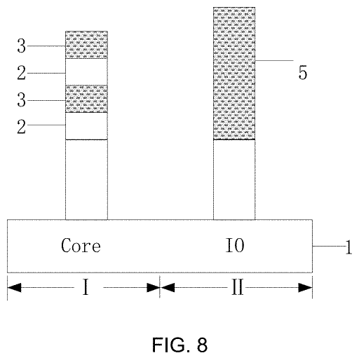

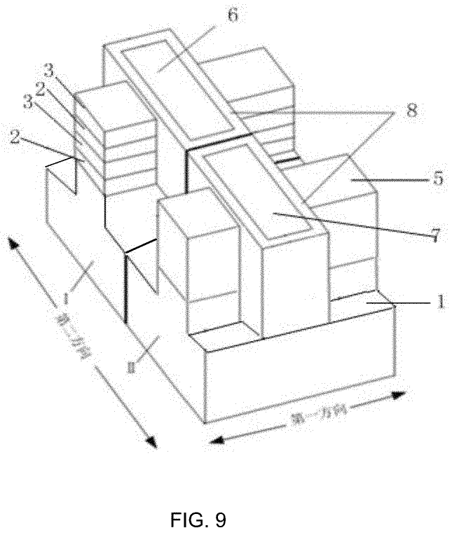

It should be noted that, a dry anisotropic etching method is used to etch the substrate 1, the stack of the first epitaxial layer 3 and the sacrificial layer 2 in core device region I, and the second epitaxial layer 5 in input/output device region II to form a first fin protruding from the substrate corresponding to the core device region I and a second fin protruding from the substrate corresponding to the input/output device region II, which extend along a first direction (see FIG. 8), where the first direction may be defined as an arbitrary direction, and the first direction in this embodiment is a direction perpendicular to the paper surface or the screen. The trench between the two fins is formed on the substrate 1 after the substrate 1 is etched. In the actual device fabricating process, it may not form only two fins. There are many other fins parallel to the two fins on the outside of the first fin and the second fin along the first direction. In this embodiment, only two fins are drawn, therefore, a trench is also formed in the figure between the outsides of the two fins and the substrate 1. The trench is filled to form shallow trench isolation STI 9 (see FIG. 9), which isolates the core device region I from the input/output device region II. In order to achieve the exposure of the first and second fins to facilitate the subsequent fabrication of the devices, the thickness of the shallow trench isolation STI 9 is smaller than the depth of the trench.

S104: Forming a first dummy gate 6 extending in the second direction on the first fin and forming a spacer 8 on a sidewall of the first dummy gate 6; and forming a second dummy gate 7 extending in the second direction on the second fin and forming a spacer 8 on a sidewall of the second dummy gate 7, wherein the second direction and the first direction are orthogonal in a plane where the substrate 1 is located, as shown in FIG. 9.

It should be noted that the first dummy gate 6 crosses the first fin in the second direction and cover a portion of the first fin along the first direction, and the second dummy gate 7 crosses the second fin in the second direction and cover a portion of the second fin along the first direction. The first dummy gate 6 and the second dummy gate 7 are formed at the same time. The materials of the first dummy gate 6 and the second dummy gate 7 include poly silicon or single crystal silicon.

After the first dummy gate 6 and the second dummy gate 7 are formed, a sidewall 8 is formed on both the sidewall of the first dummy gate 6 and the sidewall of the second dummy gate 7. Specifically, spacer material is deposited. And then the spacer material is etched by an anisotropic etching process, and a certain thickness of the spacer material on the sidewalls of the first dummy gate 6 and the second dummy gate 7 are retained to form spaces 8. The spacer material can be silicon oxide, silicon nitride, amorphous carbon, and the deposition method can be Atomic layer deposition (ALD) and chemical vapor deposition (CVD).

Source and drain regions are formed on the first fins on both sides of the first dummy gate 6 along the first direction, and source and drain regions are formed on the second fins on both sides of the first dummy gate 7 along the first direction. Specifically, source and drain regions are formed by ion implantation, epitaxial growth, and other suitable methods. Specifically, silicon germanium is selectively epitaxially grown on the first fins exposed on both sides of the first dummy gate 6 along the first direction as source and drain regions. Silicon germanium is selectively epitaxially grown on the second fins exposed on both sides of the second dummy gate 7 along the first direction as source and drain regions.

The second direction and the first direction are orthogonal in the plane where the substrate 1 is located.

S105: Removing the first dummy gate 6 and forming the stacked nanowires or nanosheets in a portion of the first fin that is covered by the first dummy gate 6, and sequentially depositing a gate dielectric layer 10 and a metal gate layer 11 on a surface of the stacked nanowires or nanosheets to form a first gate.

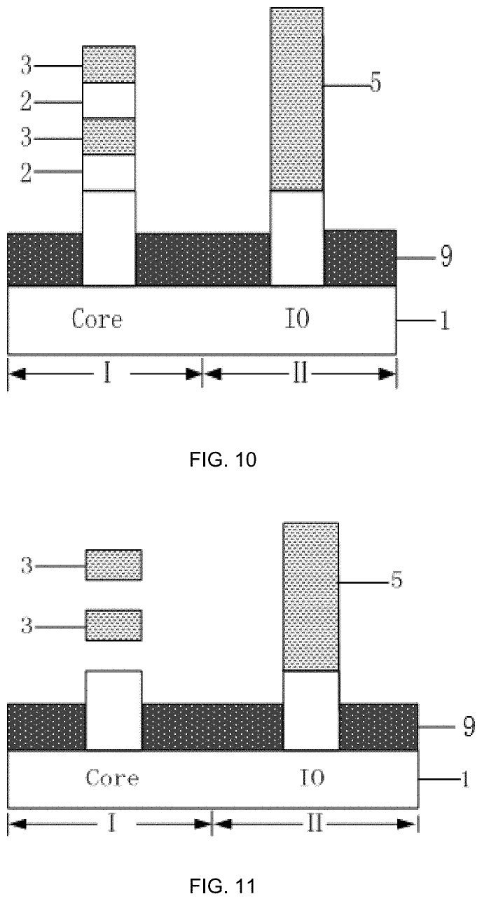

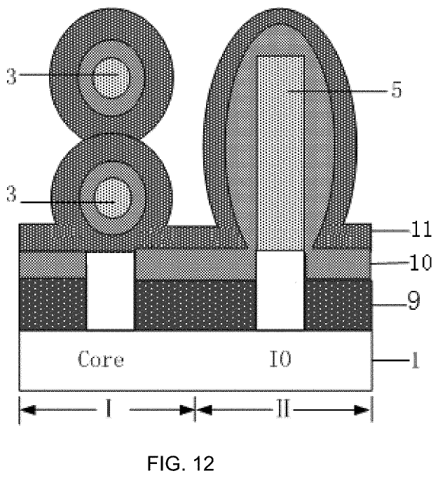

It should be noted that, after step S104, i.e., after a first dummy gate 6 and a spacer 8 are formed on the first fin, and a second dummy gate 7 and the spacer 8 are formed on the second fin, an oxide dielectric layer, i.e., first oxide dielectric layer, is deposited on the entire surface of the core device region I and the input/output device region II. The first oxide dielectric layer of a certain thickness is removed by a CMP chemical mechanical polishing process, and the first dummy gate 6 and the second dummy gate 7 are exposed on the top surface firstly. Then, a second mask layer is formed on the surface of the input/output device region II by the photolithography process to cover the entire input/output device region II. The first dummy gate 6 in the core device region I is removed to expose the first fin in the core device region I. Next, the sacrificial layer in the exposed first fin is removed. Since only the portion of the first fin that is covered by the first dummy gate 6 is exposed, stacked nanowires or nanosheets composed of a first epitaxial layer 3 is formed, along the first direction, in the portion of the first fin (see FIG. 11). The stacked nanowires or nanosheets are released to form a gap penetrating the sacrificial layer in the second direction. The second mask layer covering the surface of the input/output device region II is removed, and a gate dielectric layer 10 and a metal gate layer 11 are sequentially deposited on the stacked nanowires or nanosheets to form a first gate (see FIG. 12). Specifically, a gate dielectric layer 10 and a metal gate layer 11 are deposited on the entire surface of the first fin firstly, and then polished by a CMP chemical mechanical polishing process, leaving only the gate dielectric layer 10 and the metal gate layer 11 around the stacked nanowires or nanosheets so as to form the first gate, i.e., the first gate is a surrounding-gate structure. A gate dielectric layer 10 and a metal gate layer 11 are also sequentially deposited on the shallow channel isolation STI 9 corresponding to the core device region I. The first gate is a four-sided gate structure, and the first gate includes a gate dielectric layer 10 and a metal gate layer 11. Specifically, the gate dielectric layer 10 includes silicon dioxide and/or high-K dielectric materials such as hafnium dioxide, and the metal gate layer 11 includes metal gates such as TaN and TiN and metal materials. The metal materials include tungsten, aluminum, copper, and the like, which are not limited here.

S106: Removing the second dummy gate 7, and sequentially depositing a gate dielectric layer 10 and a metal gate layer 11 on the surface of a portion of the second fin that is covered by the second dummy gate along the second direction to form a second gate; and forming an input/output device of FinFET structure compatible with the stacked nanowires or nanosheets in the input/output device region II.

It should be noted that after the first gate is formed in the core device region I in step S105, a first mask layer is deposited and patterned on the surface of the device to cover the entire core device region I and then the second dummy gate 7 is removed to expose the second fin in the input/output device region II. The first mask layer covering the surface of the core device region I is removed, and a gate dielectric layer 10 and a metal gate layer 11 are sequentially deposited on the surface of the portion of the second fin that is covered by the second dummy gate 7 along the second direction to form a second gate. The second gate is a triple-gate structure. Specifically, the gate dielectric layer 10 and the metal gate layer 11 are deposited on the entire surface of the second fin, and then polished by a CMP chemical mechanical polishing process, leaving only the gate dielectric layer 10 and the metal gate layer 11 on the second fin. A gate dielectric layer 10 and a metal gate layer 11 are also sequentially deposited on the shallow trench isolation STI 9 corresponding to the input/output device region II (see FIG. 12). Specifically, the gate dielectric layer 10 includes silicon dioxide and/or high-K dielectric materials such as hafnium dioxide, and the metal gate layer 11 includes metal gates such as TaN and TiN and metal materials. The metal materials include tungsten, aluminum, copper, and the like, which are not limited herein. Thus, an input/output device of FinFET structure compatible with the stacked nanowires or nanosheets in the core device region I is formed in the input/output device region II.

For the core device region I and the input/output device region II, the first mask layer can also be used to cover the surface of the core device region I firstly, and then the second dummy gate 7 in the input/output device region II is removed, and then the first mask layer on the surface of the core device region I is removed. A gate dielectric layer 10 and a metal gate layer 11 are deposited on the entire surface of the second fin, and then polished by a CMP chemical mechanical polishing process, only leaving the gate dielectric layer 10 and the metal gate layer 11 on a portion of the second fin that is covered by the second dummy gate 7, i.e., a second gate is formed on the second fin. Then, the second mask layer is applied to cover the surface of the input/output device region II. The first dummy gate 6 is removed, and the sacrificial layer in a portion of the first fin that is covered by the first dummy gate 6 is removed. Stacked nanowires or nanosheets are formed on the portion of the first fin, and a gate dielectric layer 10 and a metal gate layer 11 are deposited on the entire surface of the first fin, and then polished by a CMP chemical mechanical polishing process, leaving the gate dielectric layer 10 and the metal gate layer 11 around the stacked nanowires or nanosheets to form a first gate, and the first gate is a surrounding gate structure. That is, the first gate in the core device region I can be formed firstly, and then the second gate in the input/output device region II can be formed. Or, the second gate in the input/output device region II can be formed firstly, and then the first gate in the core device region I can be formed. This is not specifically limited herein.

For the triple-gate structure formed in the input/output device region II, it is not necessary to consider the problem of depositing the gate dielectric layer 10 or the metal gate layer 11 in the gap between the nanowires or the nanosheets. This solves the problem caused by a small distance between the nanowires or nanosheets in the core device region I after release, which causes that it is difficult to fill the metal gate and even if the metal gate is filled partially, the input/output electrical performance will still be poor.

Referring to FIG. 12, the present disclosure also provides a FinFET with an input/output device compatible with stacked nanowires or nanosheets, in which the stacked nanowires or nanosheets are integrated with the input/output device compatible with stacked nanowires or nanosheets and the input/output device is FinFET structure, comprising:
a substrate 1 comprising a first region I and a second region II;
a first fin extending along a first direction on a substrate in the first region I;
wherein the first fin includes a plurality of first epitaxial layers 3, and the plurality of first epitaxial layers 3 are arranged at intervals, wherein the plurality of first epitaxial layers in a portion of the first fin are formed as stacked nanowires or nanosheets arranged at intervals;
a first gate surrounding the stacked nanowires or nanosheets;
a second fin comprising a second epitaxial layer 5 and extending along a first direction on a substrate in the second region II;
a second gate extending in a second direction on the second fin;
the first direction and the second direction are orthogonal in the plane where the substrate 1 is located.

Preferably, the core device further includes source and drain regions formed in the first fin on both sides of the first gate along the first direction and the input/output device further includes source and drain regions formed in the second fin on both sides of the second gate along the first direction.

Preferably, the first region I is adapted to form a core device; the second region II is adapted to form an input/output device;

The material of the first epitaxial layer 3 includes silicon or silicon germanium; the material of the second epitaxial layer 5 includes any one of silicon, silicon germanium, germanium, or a III-V compound; and the material of the substrate 1 includes silicon or silicon on insulator;

The first gate and the second gate each include a gate dielectric layer 10 and a metal gate layer 11, and the gate dielectric layer 10 includes silicon dioxide and/or hafnium dioxide.

The structure of the input/output device compatible with the stacked nanowires or nanosheets provided by the present disclosure is a FinFET structure. A single-layer structure composed of the second epitaxial layer 5, instead of the stacked nanowire structure, is applied in the input/output device region II, therefore, the formed second fin is also a single-layer structure, and a gate dielectric layer 10 and a metal gate layer 11 are formed on the top and sidewalls of the second fin along the second direction. It is not necessary to form the gate dielectric layer 10 and the metal gate layer 11 at the gap between the stacked nanowires or nanosheets after release. This will not involve the problem that the distance is very small between the stacked nanowires or nanosheets after release and it is difficult to fill the metal gate, and even if the metal gate is filled partially, the electrical performance of the input/output device will still be poor.

The above descriptions are merely preferred embodiments of the present disclosure and are not intended to limit the present disclosure. For those skilled in the art, the present disclosure may have various modifications and changes. Any modification, equivalent replacement, and improvement made within the spirit and principle of the present disclosure shall be included in the protection scope of the present disclosure.

What is claimed is:

1. A method for fabricating semiconductor device, comprising:
providing a substrate comprising a first region and a second region, and forming sacrificial layers and first epitaxial layers alternately stacked on the substrate;
removing the first epitaxial layers and the sacrificial layers in the second region, and forming a second epitaxial layer on the substrate in the second region;
etching the substrate, the first epitaxial layers and the sacrificial layers in the first region, and the second epitaxial layer in the second region, and forming shallow trench isolation STI, a first fin protruding from the substrate in the first region, and a second fin protruding from the substrate in the second region, wherein the first fin and the second fin both extend in a first direction;
forming a first dummy gate extending in a second direction across the first fin whilst forming a second dummy gate extending in the second direction across the second fin, and forming a first spacer on a sidewall of the first dummy gate whilst forming a second spacer on a sidewall of the second dummy gate, wherein the second direction and the first direction are orthogonal in a plane where the substrate is located;
removing the first dummy gate and forming the stacked nanowires or nanosheets in a portion of the first fin that is covered by the firs dummy gate, and sequentially depositing a first gate dielectric layer and a first metal gate layer on a surface of the stacked nanowires or nanosheets to form a first gate;
removing the second dummy gate and sequentially depositing a second gate dielectric layer and a second metal gate layer on a surface of a portion of the second fin that is covered by the second dummy gate, in the second direction to form a second gate.

2. The method according to claim 1, wherein removing the first epitaxial layer and the sacrificial layer in the second region and forming a second epitaxial layer on the substrate in the second region comprises:
depositing a hard mask on a top surface of the first epitaxial layer, forming a pattern on the hard mask using a photolithography process, and defining the second region;
selectively removing the first epitaxial layer and the sacrificial layer in the second region by using a dry etching or a wet etching process;
performing selective epitaxy of the second epitaxial layer on the substrate in the second region;
planarizing or etching back the second epitaxial layer, so that the top of the second epitaxial layer is flush with the top of the hard mask in the first region;
removing the hard mask, so that a difference between heights of the first region and the second region is equal to a thickness of the hard mask.

3. The method according to claim 1, wherein removing the first dummy gate and forming the stacked nanowires or nanosheets in a portion of the first fin that is covered by the first dummy gate comprises:
removing the sacrificial layer in the portion of the first fin that is covered by the first dummy gate to form the stacked nanowires or nanosheets composed of the first epitaxial layer.

4. The method according to claim 1, wherein after forming the first and second dummy gates and the first spacer and the second spacer, the method further comprises: epitaxially growing source and drain regions on the first fin on both sides of the first dummy gate along the first direction, and epitaxially growing source and drain regions on the second fin on both sides of the second dummy gate along the first direction.

5. The method according to claim 1, wherein;
when material of the first epitaxial layer is silicon, material of the sacrificial layer is silicon germanium, when material of the first epitaxial layer is silicon germanium, material of the sacrificial layer is silicon;
material of the second epitaxial layer comprises any one of silicon, silicon germanium, germanium, or III-V compound; and
material of the substrate comprises silicon or silicon-on-insulator.

6. The method according to claim 1, wherein the first region is adapted to form a core device;
the second region is adapted to form the input/output device.

7. The method of claim 1, wherein the first gate dielectric layer and the second gate dielectric layer comprise silicon dioxide and/or hafnium dioxide.

8. A semiconductor device, comprising:
a substrate comprising a first region and a second region;
a first fin extending in a first direction on the substrate in the first region;
a first gate extending along the second direction across the first fin;
wherein the first fin comprises a plurality of first epitaxial layers, and in a portion of the first fin that is covered by the first fin, the plurality of first epitaxial layers are arranged at intervals, and in a portion of the first fin that is not covered by the first fin, the plurality of first epitaxial layer and a plurality of sacrificial layers are alternately stacked;
a second fin comprising a second epitaxial layer and extending in the first direction on the substrate in the second region;
a second gate extending in a second direction on the second fin;
wherein the first direction and the second direction are orthogonal in a plane where the substrate is located.

9. The semiconductor device according to claim 8, wherein the first region is adapted to form a core device; and the second region is adapted to form an input/output device;
material of the first epitaxial layer is silicon or silicon germanium; material of the second epitaxial layer comprises any one of silicon, silicon germanium, germanium, or III-V compound; and material of the substrate comprises silicon or silicon on insulator;
the first gate and the second gate each comprise a gate dielectric layer and a metal gate layer, and the gate dielectric layer comprises silicon dioxide and/or hafnium dioxide.

10. The semiconductor device according to claim 9, wherein the core device further comprises source and drain regions formed on the first fin on both sides of the first gate along the first direction, and the input/output device further comprises source and drain regions formed on the second fin on both sides of the second gate along the first direction.
